(19) United States
(12) Patent Application Publication
(10) Pub. No.: US 2004/0140122 A1
(43) Pub. Date: Jul. 22, 2004

(54) Product comprising a substrate and a chip attached to the substrate

(76) Inventors: Rainer Moll, Graf (AT); Joachim Heinz Schober, Graz (AT)

Correspondence Address: US Philips Corporation, Intellectual Property Department, PO Box 3001, Briarcliff Manor, NY, 10510, US

(21) Appl. No.: 10/477,874

(22) PCT Filed: May 16, 2002
(86) PCT No.: PCT/IB02/01802

(30) Foreign Application Priority Data
May 17, 2001 (EP) 01890147.0

(51) Int. Cl. H05K 1/16

(52) U.S. Cl. 174/260

(57) ABSTRACT

In a product (4) with a component (19) which has at least one component contact (20, 21) formed by a metal bump (20, 21), and with a substrate (15) which has at least one substrate contact (16, 17), an electrically conductive intermetallic connection (34, 35) is formed in each case between a component contact (20, 21) and a substrate contact (16, 17) and between the component (19) and the substrate (15) is provided a protective layer (26) formed using a foil which was fixedly connected with the substrate (15) before formation of the electrically conductive intermetallic connection (34, 35) existing in each case between a component contact (20, 21) and a substrate contact (16, 17) and which can be softened at least once under the effect of heat.

The invention relates to a product with a component in particular a chip which has at least one component contact formed by a metal bump, and with a substrate with at least one substrate contact, where a component contact and a substrate contact are in each case connected electrically conductively and to protect the connection and contacts a protective layer of plastic is provided.

Such a product is known from patent document U.S. Pat. No. 5,858,149 A. In the known product the component is formed by a chip which has several chip contacts as component contacts, of which each chip contact is formed by a gold bump produced using a wire bond device and therefore formed drop-like before being electrically connected with a substrate contact of a substrate. Such drop-like gold bumps tend to shift sideways when placed on the substrate contact and can even be destroyed, which is disadvantageous. In production of the known product a thermo-compression process is used where, in the course of this process, the gold bump is only brought into electrically conductive contact with the substrate contacts by pressing the gold bump and substrate contacts together, -and where in the course of this process, a coating-like plastic mass between the chip and the substrate is solidified at least substantially by the effect of heat and hence holds the chip and substrate together and also maintains the electrically conductive connection, i.e. ensures that the gold bump and substrate contact are pressed together and at the same time performs the protective function. As the gold bumps and substrate contacts are held in electrically conductive connection only by being pressed together, no secure electrically conductive connection which is not sensitive to mechanical stress can be guaranteed. With regard to the coating-like plastic mass it should be stated that this plastic mass must be applied to the substrate before the chip is connected to the substrate, and because of the non-solid consistency of the plastic mass, the substrate with the plastic mass thereon must be processed relatively soon after application of the plastic mass and can only be transported further in a very restricted scope and cannot in practice be temporarily stored as this causes too great a change in consistency and where applicable the volume of the plastic mass applied and hence leads to a restriction or total loss of function suitability of the plastic mass.

It is an object of the invention to eliminate the difficulties arising with the known product or production of the known product and achieve an improved product.

To achieve this object in a product according to the invention features according to the invention are provided so that a product according to the invention can be characterized in the following manner:

Product with a component which has at least one component contact formed by a metalbump, and with a substrate with at least one substrate contact, where in each case between a component contact and a substrate contact an electrically conductive connection exists which is formed by an intermetallic connection produced under the effect of pressure and heat, and where between the component and the substrate a protective layer is provided consisting of plastic and intended to protect the electrically conductive intermetallic connection existing in each case between a component contact and a substrate contact and formed using a foil which was fixedly connected with the substrate before production of the electrically conductiveintermetallic contact in each case between a component contact and a substrate contact and which can be softened at least once under the effect of heat.

By providing the features according to the invention a product is achieved which is simple t6 produce and simple in design in which a particularly stable, permanent and ageing-resistant connection is present between each metal bump provided as a component contact and the substrate contact connected with this metal bump. The advantage is also achieved that a product according to the invention can be produced in the manner that the component necessary to form the protective layer can be applied to the starting product for the substrate in the form of a foil, which brings the great advantage that the starting product and the foil connected with this can easily be handled and if necessary transported over large distances and if necessary can also be stored over longer time periods without a change in the consistency or form of the foil applied as the starting product for the protective layer to the starting product for the substrate. A further advantage is that for a foil, by means of which the protective layer can be achieved by use of a thermo-compression process, a multiplicity of embodiments are available. For such a foil so-termed thermoplastics can be used which can be softened or melted repeatedly. However, advantageously use is made of duroplasts which can be softened or melted only once and can no longer be modified after softening and subsequent hardening into their hardened consistency.

In a product according to the invention the substrate contact can consist of a single layer of a particular metal where the metal for example can be tin, silver or gold, which is however relatively expensive. It has proved particularly advantageous if the substrate contact consists of a base layer of metal and a cover layer of metal applied to this base layer and if the intermetallic connection achieved under the effect of pressure and heat is formed using the cover layer. Such a design has proved particularly advantageous in tests. Such a design offers the advantage that the substrate contacts can consist largely of a cheap base layer and that only the cover layer connected with the base layer requires a higher financial expenditure to achieve an intermetallic connection with this cover layer using a thermo-compression process. Preferably such a cover layer consists of tin.

In a product according to the invention it has proved particularly advantageous if the component has at least one metal bump applied galvanically. Such a design is of particularly great advantage in the present context because galvanically applied metal bumps, in contrast to the known drop-like metal bumps, have an essentially cuboid shape, so that because of the cuboid shape the sideways movement of the metal bump in the course of the thermo-compression process can be avoided with a high degree of certainty. Such metal bumps applied galvanically preferably consist of gold, however other bump technologies are. possible with palladium bumps or “electroless” nickel gold bumps.

A product according to the invention can be produced preferably as a module for a data carrier for contactless communication and/or communication via contacts. Such a product according to the invention can however also be formed as a data carrier for communication with and/or without contacts, which is also highly advantageous.

The aspects above and further aspects of the invention are apparent from the examples described below and are explained using these examples.

The invention will be further described with reference to two examples of embodiments shown in the drawings, to which however the invention is not restricted.

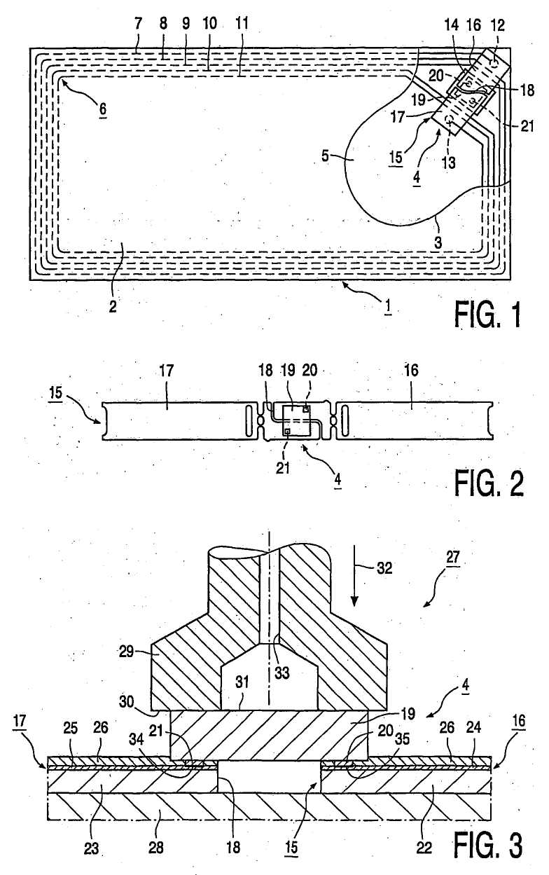

FIG. 1 shows diagrammatically a top view of a data carrier for contactless communication according to an example of the invention, which data carrier contains a module according to a first example of the invention.

FIG. 2 shows in a top view a module for mounting in a data carrier for contactless communication according to a second example of the invention.

FIG. 3 shows in cross section and in a position rotated in relation to the position in FIG. 1 the module of the data carrier in FIG. 1 in a situation during production of this module, in which situation a thermo-compression process is performed.

FIG. 1 shows a data carrier 1. The data carrier 1 has a data carrier body 2 which in the present case is produced in a laminating process. The data carrier body 2 can however also be produced with an injection molding process. A part outlined with line 3 of the data carrier 2 is not shown in order to give a clear view onto a module 4 of the data carrier 1.

During production of data carrier 1, onto a carrier foil 5 subsequently included in the laminating process, a transfer coil 6 is applied using a screen printing process. Other processes are however also possible such as etching, punching or embossing. The transfer coil 6 shown diagrammatically in FIG. 1 has windings 7, 8, 9, 10 and 11 which according to the view in FIG. 1 lie on the carrier foil 5. The free end of the outermost winding 7 is connected with a first coil connection 12. The free end of the innermost winding 11 is connected with a second coil connection 13. At the same time as production of the transfer coil 6, also a protective shield 14 is produced which lies between the two windings 9 and 10 of the transfer coil 6. The purpose of the protective shield 14 will be discussed later.

The data carrier 1 is as already stated fitted with a module 4. The module 4 comprises a substrate 15 which in the present case consists of two substrate contacts 16 and 17 arranged lying next to each other in one plane and separated by an essentially S-shaped air gap 18. The module 4 has also an electronic component 19 here formed by a chip 19. The chip 19 has as component contacts two chip contacts 20 and 21where the first chip contact 20 is electrically conductively connected with the first substrate contact 16 and the second chip contact 21 with a second substrate contact 17 in each case via an electrically conductive connection. It is also noted that the first substrate contact 16 is electrically conductively connected with the first coil connection 12 and the second substrate contact 17 with the second coil connection 13. The electrically conductive and mechanical connections between the first substrate contact 16 and the first coil connection 12 and between the second substrate contact 17 and the second coil connection 13 are each formed by a crimp connection. The chip 19 in the data carrier 1 assumes such a position that the chip 19 with its side facing away from the substrate contacts 16 and 17 lies opposite the protective shield 14'so that the chip 19 is protected from disruptive light influences by means of the protective shield 14, where the protective shield 14 also forms a heat sink.

In FIG. 3 the module 4 of data carrier 1 in FIG. 1 is described in more detail.

The chip contacts 20 and 21 of the chip 19 are each formed by a metal bump 20 and 21, namely a gold bump. It should be noted that each gold bump is applied galvanically on pads of the chip 19, which pads are not shown in FIG. 3. By galvanic application of the gold bumps the great advantage is achieved that the gold bumps 20 and 21 essentially have a cuboid shape.

With regard to the two substrate contacts 16 and 17 it is to be noted that each of the two substrate contacts 16 and 17 consists of a base layer 22, 23 respectively, of metal, preferably of copper or a copper-tin alloy, and a cover layer 24, 25 respectively, of metal applied to the base layer 22, 23, respectively.

In the module 4, between the chip 19 and substrate 15 is provided a protective layer 26. The protective layer 26 consists of plastic and is provided to protect the electrical connection existing in each case between a chip contact 20 or 21 and a substrate contact 16 or 17. The protective layer 26 is also intended for insulation purposes, namely for insulating the substrate contacts 16 and 17 from the coil windings 7, 8, 9, 10 and 11. It should also be stated that the crimp connections between the two substrate contacts 16 and 17 and the two coil connections 12 and 13 exist over the protective layer 26.

In the module 4 the protective layer 26 is particularly advantageously formed using a foil which was fixedly connected with substrate 18 before formation of the electrically conductive connection existing ini each case between a chip contact 20 or 21 and a substrate contact 16 or 17, and in the present case can be softened once under the application of heat.

In the module 4, the two chip contacts 20 and 21 are formed by a metal bump 20 and 21, and the two substrate contacts 16 and 17, or more precisely the covet layers 24 or 25 of each substrate contact 16 and 17, are designed to form an intermetallic connection 34 and 35 achievable under the effect of pressure and heat, as indicated diagrammatically by a thicker line in FIG. 3. To this end the cover layer 24 or 25 of each of the two substrate contacts 16 and 17 consists of tin.

FIG. 3 shows in a highly diagrammatic manner a device 27 for carrying out a thermo-compression process. The device 27 has a table 28 on which the substrate 15 can be laid as shown in FIG. 3. The table 28 can be heated in a manner not shown in detail using heat sources not shown, for example using thermodes. Using the table 28 the substrate contacts 16 and 17 and the foil for forming the protective layer. 26 can be heated. The device 27 also has a die 29 which can be placed with a surface 30 on the free limiting surface 31 of the chip 19. The die 29 can also be heated using heat sources not shown so that via its limiting surface 30 heat energy can be transferred to the chip 31 and in particular to the chip contacts 20 and 21. The die 29 can also be adjusted using the adjustment means not shown in the direction of an arrow 32 in order to exert pressure, by means of the die 29, on the chip 19 and consequently on the chip contacts 20 and 21 and hence indirectly on the areas of the substrate contact 16 and 17 lying opposite the chip contacts 20 and 21. Finally the die 29 is also connected with an air extraction device, not shown, by means of which air can be extracted via a channel 33 provided in the die 29 in order to guarantee perfect co-operation between the die 29 and the chip 19.

After module 4 has been brought into the device 27, the die 29 of device 27 is moved in the direction of arrow 32 such that a particular pressure is exerted on chip 19 and consequently on chip contacts 20 and 21 and the opposite areas of substrate contacts 16 and 17. Furthermore here both the table 28 and the die 29 are heated such that a particular temperature is achieved in the area of chip contacts 20 and 21 and the opposite cover layers 24 and 25 of substrate contacts 16 and 17. Under the effect of pressure and heat firstly the foil already connected with the substrate 15 or substrate contacts 16 and 17 softens, with the result that chip contacts 20 and 21 i.e. gold bumps 20 and 21 protrude through the softened foil until they are pressed against the cover layers 24 and 25 of the substrate contacts 16 and 17 and subsequently intermetallic connections are formed between the chip contacts 20 and 21 and cover layers 24 and 25 i.e. substrate contacts 16 and 17. By heating the foil already connected with the substrate 15, the said softening of this foil occurs which leads not only to a change in consistency but also to a change in chemical- physical properties of the film and hence leads to formation of the protective layer 26. Then the die 29 is moved further against the arrow 32 so that the module 4 now produced can be removed from the device 29 SO the protective layer 26 will harden. Where applicable the module 4 can then be brought into an oven to achieve a definitive hardening of the protective layer 26, so that subsequently the definitive protective layer 26 is obtained.

In the description above the great advantage is achieved that between chip contacts 20 and 21 of chip 19 and substrate contacts 16 and 17 of substrate 15 intermetallic connections 34 and 35 exist which have a high strength and high ageing resistance, which is very advantageous. Furthermore in this design the advantage is achieved that the protective layer 26 is formed using a film already applied to the substrate 15, which is advantageous with regard to simple handling during production of module 4. Furthermore, this is also advantageous as the intermediate product formed from the substrate 15 and the foil used to form the protective coating 26 can easily be transported over large distances and also stored for long periods without harmful influences occurring.

FIG. 2 shows a further module 4, the structure of which corresponds in detail practically to the structure of module 4 in FIGS. 1 and 3. In module 4 according to FIG. 2 the design of the air gap 18 between the substrate contacts 16 and 17 is different. In this case the air gap 18 is formed so as to be also essentially S-shaped but in this case the air gap 18 ends at the side next to the chip 19, and the air gap has a section running essentially parallel to the strip-like substrate contacts 16 and 17.

It should be stated that for the purposes of generating heat, in a device 27 designed accordingly, ultrasound can also be used.

The invention has been described above using two products, namely a data carrier often known as a chip card and a module for such a data carrier. Here as a component a chip is provided which has two chip contacts. The measures according to the invention can also be used advantageously with other products, for example RF tags or RF labels, or products with a chip with more than two chip contacts. The invention can also however be used in a product with a diode which has only one diode contact formed by a metal bump, where a second contact of the diode can then be formed by the diode housing.

1. Product (1,4) with a component (19) which has at least one component contact (20, 21) formed by a metal bump (20, 21), and with a substrate (15) with at least one substrate contact (16, 17), where in each case between a component contact (20, 21) and a substrate contact (16, 17) an electrically conductive connection exists which is formed by an intermetallic connection (34, 35) produced under the effect of pressure and heat, and where between the component (19) and the substrate (15) a protective layer (26) is provided consisting of plastic and intended to protect the electrically conductive intermetallic connection (34, 35) existing in each case between a component contact (20, 21) and a substrate contact (16, 17) and formed using a foil which was fixedly connected with the substrate (15) before production of the electrically conductive intermetallic contact (34, 35) in each case between a component contact (20, 21) and a substrate contact (16, 17) and which can be softened at least once under the effect of heat.

2. A product (1; 4) as claimed in claim 1, where the at least one substrate contact (16, 17) consists of a base layer (22, 23) of metal and a cover layer (24, 25) of metal applied to the base layer (22, 23), where the intermetallic connection (34, 35) achieved under the effect of pressure and heat is formed by means of the cover layer (24, 25).

3. A product (1; 4) as claimed in claim 1, where the component (19) has at least one metal bump (20, 21) applied galvanically.

4. A product (4) as claimed in claim 1, which product (4) is formed as a module (4) for a data carrier (1) for contactless communication and/or communication via contacts.

5. A product (1) as claimed in claim 1, which product (1) is formed as a data carrier (1) for contactless communication and/or communication via contacts.
